(19) United States
(12) Patent Application Publication
(10) Pub. No.: US 2023/0193463 A1
(43) Pub. Date: Jun. 22, 2023

(54) Gas Distribution Apparatuses

(71) Applicant: Applied Materials, Inc., Santa Clara, CA (US)

(72) Inventors: Shashidhara Patel H B, Bangalore (IN); Madhuri Kalva, Fremont, CA (US); Sreenivasa Rao Nunna, Bangalore (IN); Shih Chung Chen, Cupertino, CA (US); Yongjing Lin, San Jose, CA (US); Bin Cao, Fremont, CA (US)

(73) Assignee: Applied Materials, Inc., Santa Clara, CA (US)

(21) Appl. No.: 18/065,742

(22) Filed: Dec. 14, 2022

Related U.S. Application Data
(60) Provisional application No. 63/290,109, filed on Dec. 16, 2021.

(51) Int. Cl. C23C 16/455; H01J 37/32

(52) U.S. Cl. CPC C23C 16/45565; H01J 37/32458; H01J 37/32449; C23C 16/45544

(57) ABSTRACT

Gas distribution apparatuses, e.g., showerheads, comprise passages having a first conical bore section, a small bore section, and a second conical bore section. The first conical bore sections comprise a first non-perpendicular wall angle relative to a back surface of a faceplate. The second conical bore sections comprise a second non-perpendicular angle to a front surface of the faceplate. The conical sections including non-perpendicular angles are effective to mitigate and/or eliminate changes in flow parameters through the passages after bead blast processes.

### CROSS-REFERENCE TO RELATED APPLICATIONS

The present application claims priority to U.S. patent application Ser. No. 63/290,109 filed on Dec. 16, 2021.

### TECHNICAL FIELD

The present disclosure generally relates to apparatuses and methods for gas distribution in semiconductor processing chambers. In particular, embodiments of the disclosure are directed to gas distribution apparatuses, e.g., showerheads, with passages having a first conical bore section, a small bore section, and a second conical bore section. The first conical bore sections comprise a first non-perpendicular wall angle relative to a back surface of a faceplate. The second conical bore sections comprise a second non-perpendicular angle to a front surface of the faceplate. The conical sections non-perpendicular angles are effective to mitigate and/or eliminate changes in flow parameters through the passages after bead blast processes.

### BACKGROUND

Many semiconductor processes involve the use of gas distribution apparatus, e.g., plates and/or showerheads, in processing chambers. Controlling of particle adders and residue flakes on showerheads of semiconductor processing chambers can be overcome by higher surface roughness. Surface roughening can be achieved in a variety of ways. Bead blasters may roughen a substrate by bombarding the substrate with beads or particles, for example, ceramic beads or particles. The roughness achieved by bead blasters may be based on a force used to fire the beads, bead materials, bead sizes, distance of the bead blaster from the substrate, processing duration, and so forth.

With bead blast methods, drawbacks include damages to critical holes edges of showerheads, which affects hole sizes, conductance, and life span.

Generally, there is a need in the art to avoid damage to gas passages and holes during bead blast processes and to increase useful processing life of gas distribution apparatuses such as showerheads.

### SUMMARY

One or more embodiments are directed to gas distribution apparatuses comprising: a faceplate and a plurality of passages extending through a thickness of the faceplate. The faceplate has a front surface and a back surface defining the thickness. Each of the passages has a first conical bore section, a small bore section, and a second conical bore section. Each of the first conical bore sections comprise a first non-perpendicular wall angle relative to the back surface of the faceplate. Each of the small bore sections is defined by a cylindrical wall. Each of the second conical bore sections comprise a second non-perpendicular angle to the front surface of the faceplate.

Another embodiment provides: showerhead comprising: a faceplate and a plurality of uniformly-sized and -shaped passages extending through a thickness of the faceplate. The faceplate has a front surface and a back surface defining the thickness. Each of the passages has a first conical bore section, a small bore section, and a second conical bore section. Each of the first conical bore sections comprise a first non-perpendicular wall angle relative to the back surface of the faceplate, and an entry angle in a range of greater than or equal to 20° to less than or equal to 40°. Each of the small bore sections is defined by a cylindrical wall that is co-axial with a longitudinal axis of each of the passages. Each of the second conical bore sections comprise a second non-perpendicular angle to the front surface of the faceplate, and an exit angle is in a range of greater than or equal to 20° to less than or equal to 40°.

Additional embodiments are directed to semiconductor processing chambers comprising: a housing, a substrate support having a support surface, and any gas distribution apparatus or showerhead disclosed herein, the front surface of the faceplate spaced a distance from the support surface; and a controller configured to provide a flow of gas to the gas distribution plate.

Other embodiments provide methods of roughening gas distribution apparatuses comprising: removing any gas distribution apparatus or showerhead disclosed herein from a semiconductor processing chamber; and exposing the gas distribution apparatus or showerhead to a bead blaster process to independently contact the front surface and/or the back surface of the gas distribution apparatus.

Further embodiments are directed to non-transitory computer readable mediums. The non-transitory computer readable mediums include instructions. When the instructions are executed by a controller of a processing chamber according to any embodiment herein, the processing chamber performs an operation of: providing a flow one or more gasses to a gas distribution plate according to any embodiment herein; and conducting a semiconductor process in the processing chamber.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a cross-section schematic view of a comparative gas passage;

FIG. 2 shows a cross-section schematic view of a gas passage in accordance with one or more embodiments;

FIG. 3 shows a cross-sectional schematic view of a gas passage in accordance with one or more embodiments;

FIG. 4 shows a cross-sectional schematic view of a processing chamber in accordance with one or more embodiments;

FIG. 5 shows a flowchart of a method of a roughening a gas distribution apparatus in accordance with one or more embodiments; and

FIG. 6 is a schematic representation of a processing platform in accordance with one or more embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label. The cross-hatch shading of the components in the figures are intended to aid in visualization of different parts and do not necessarily indicate different materials of construction.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor”, “reactant”, “reactive gas” and the like are used interchangeably to refer to any gaseous species that can react with the substrate surface, or with a film formed on the substrate surface.

Bead blast processes that help to create surface roughness needed for various semiconductor processing techniques can also damage the gas passages or holes in the gas distribution apparatuses, e.g., gas distribution plates or showerheads. To mitigate and/or avoid damages induced during bead blast processes, showerheads comprise gas passages that include chamfered hole edges at a transition from a large bore section to a small bore section, which protects surfaces of the gas passages and thereby avoids and/or mitigates changes to flow parameters. Advantageously, the gas passages including these chamfered or conical shapes maintain flow parameters such as conductance and chemical pressure after bead blast processes. This in turn is advantageous for consistency and uniformity during semiconductor processing and for extended life of reusage during regular preventive maintenance activity.

Embodiments herein are directed to apparatuses, processing chambers, and methods of roughening a gas distribution apparatuses in semiconductor processing chambers. The gas distribution apparatuses are suitable for any type of processing chamber that utilizes precursors, reactants, reactive gases and the like to process substrate surfaces and/or form films on the substrate surface.

FIG. 1 illustrates in a cross-section schematic view a traditional or comparative gas passage 11 defined by passage walls 16, including a large bore cylindrical section 11A, a small bore cylindrical section 11C, and a conical bore section 11B. The conical bore section 11B meets the small bore cylindrical section 11C at corner/edge 38. The large bore cylindrical section 11A contacts a back surface of a faceplate at corner/edge 32, and the conical section 11B contacts a front surface of the faceplate at corner/edge 34. A transition from the large bore cylindrical section 11A to the small bore cylindrical section 11C includes a perpendicular corner/edge 36. Bead blast processes can damage the perpendicular edge 36, which in turn changes flow parameters such as conductance and pressure.

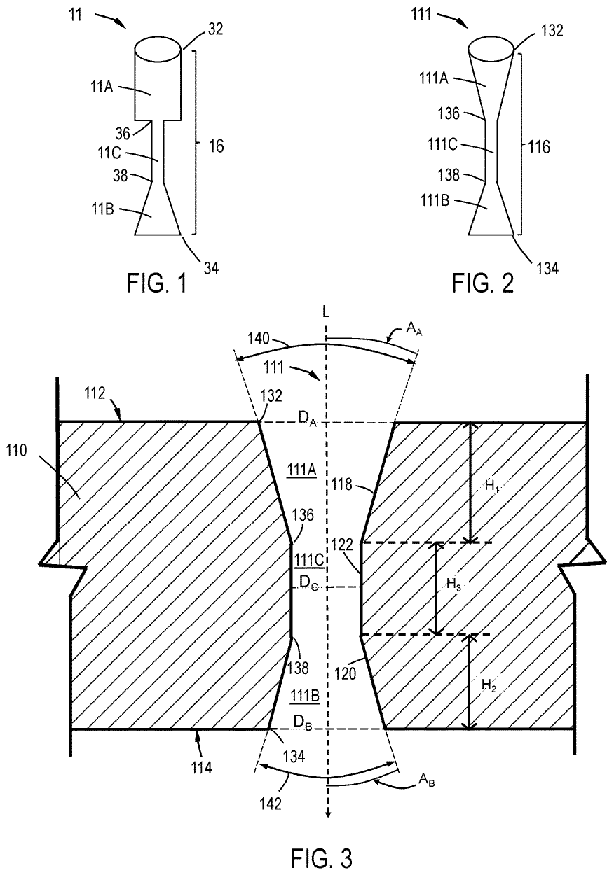

With reference to FIG. 2, providing a cross-section schematic view of a passage according to one or more embodiments, addition of a conical feature at the transition into a small bore section minimally or does not impact flow parameters. This feature advantageously facilitates maintaining uniform specifications on a wafers and increases life-spans of showerhead structures. Angle of the conical feature can be adjusted along with its height in combination with existing showerhead dimensions in order to maintain a desired pressure drop suitable for a given process. In FIG. 2, gas passage 111 defined by passage walls 116, including a first conical bore section 111A, a small bore cylindrical section 111C, and a second conical bore section 111B. The second conical bore section 111B meets the small bore cylindrical section 111C at outlet corner/edge 138. The first conical bore section 111A contacts a back surface of a faceplate at corner/edge 132, and the second conical bore section 111B contacts a front surface of the faceplate at corner/edge 134. A transition from the first conical bore section 111A to the small bore cylindrical section 111C includes an inlet corner/edge 136 that is non-perpendicular. A transition from the second conical bore section 111B to the small bore cylindrical section 111C includes an outlet corner/edge 138 that is non-perpendicular. Both the inlet corner/edge 136 and the outlet corner/edge 138 are protected during bead blast operations due to the conical-shaped sections.

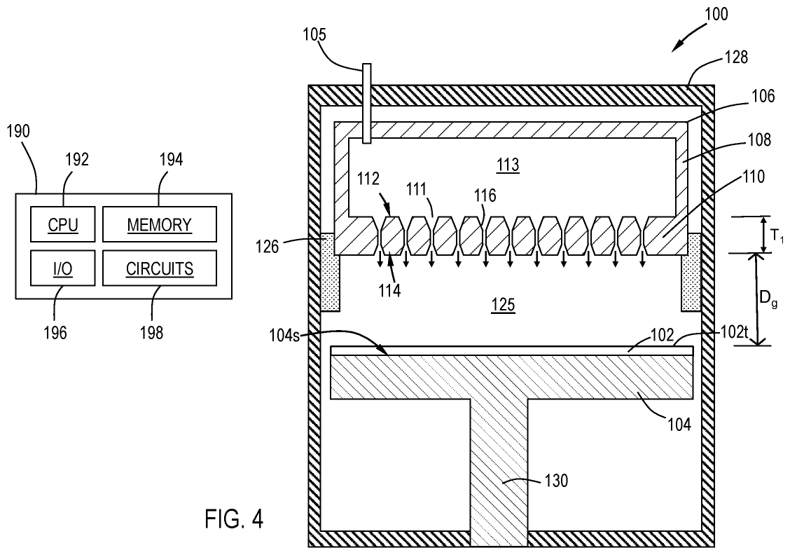

Turning to FIGS. 3-4, one or more embodiments provide a processing chamber 100 and gas passages 111. The relative sizes and dimensions are not to scale, having been exaggerated and altered for illustrative and descriptive purposes and should not be taken as limiting the scope of the disclosure. The processing chamber 100 includes a housing 128, a gas distribution apparatus, e.g., showerhead, 106, a substrate support 104 having a substrate support surface 104s, and a ceramic ring insulator 126. The processing chamber may include heating zones (not shown) for conducting thermal processes.

The showerhead 106 has a showerhead body 108 and a showerhead faceplate 110. The showerhead faceplate 110 has a front surface 114, also referred to as wafer side, and a back surface 112, also referred to as a gas side, between which defines an overall thickness (Ti) of the showerhead faceplate 110. The back surface 112 of the showerhead faceplate 110 in combination with other internal surfaces of the showerhead body 108 define a plenum 113 in fluid communication with a feed inlet 105. The showerhead faceplate 110 includes a plurality of passages 111 defined by passage walls 116, which extend from the back surface 112 through to the front surface 114 of the showerhead faceplate 110. The illustrated embodiment shows the plurality of passages 111 in fluid communication with the plenum 113 so that a gas flowing through the feed inlet 105 enters the plenum 113 and diffuses through the passages 111 in the direction of the arrows into a process gap 125 defined by the front surface 114 of the showerhead faceplate 110 and a top surface 102t of the wafer 102, spanning a distance D_{g}.

In one or more embodiments, the front surface has a roughness value in a range of greater than or equal to 24 μ-in Ra to less than or equal to 300 μ-in Ra, and all values and subranges therebetween. In one or more embodiments, the back surface has a roughness value in a range of greater than or equal to 24 μ-in Ra to less than or equal to 300 μ-in Ra, and all values and subranges therebetween. In one or more embodiments, both the front surface and the back surface each independently has a roughness value in a range of greater than or equal to 24 μ-in Ra to less than or equal to 300 μ-in Ra, and all values and subranges therebetween.

During use, the process gap 125 is defined by the top surface of the wafer 102, which is spaced the gap distance D_{g} from the front surface 114 of the showerhead faceplate 110 so that the gas from the plenum 113 contacts the wafer 102 positioned on the support surface 104s. In one or more embodiments, the processing chamber 100 is configured to deposit films by ALD. In one or more embodiments, the processing chamber 100 is configured to conduct thermal processes. In one or more embodiments, the processing chamber 100 is configured to conduct thermal ALD processes.

In the illustrated embodiments, each of the passages 111 has a back opening in at the corner/edge 132 formed by a junction of the back surface 112 and the plenum 113 and a front opening at the corner/edge 134 formed by a junction of the front surface 114 and the process gap 125. The back opening has a back surface diameter DA and the front opening has a front surface diameter DB.

The showerhead faceplate 110 illustrated may be referred to as a single channel showerhead. To pass through the showerhead faceplate 110, a gas must flow through the passages 111, creating a single flow path. The skilled artisan will recognize that this is merely one possible configuration, and should not be taken as limiting the scope of the disclosure. Showerheads may be as a dual channel showerhead in which there are two separate flow paths for a species to pass through the showerhead so that the species do not mix until emerging from the showerhead into the process gap 125.

The substrate support 104 includes the substrate support surface 104s configured to support a substrate or wafer 102 during processing. The substrate support 104 may be connected to a support shaft 130. The support shaft 130 can be integrally formed with the substrate support 104 or can be a separate component from the substrate support 104. The support shaft 130 of some embodiments is configured to rotate around a central axis of the substrate support 104. In some embodiments, the support shaft 130 is configured to move the support surface 104s closer to or further away from the front surface 114 of the showerhead faceplate 110.

In one or more embodiments, ceramic isolator 126 is in the form of a ring isolating the showerhead 106 from the housing 128.

The processing chamber 100 includes one or more feed inlets 105. For illustrative purposes, the feed inlet 105 is shown through a top surface of the housing 128. The feed inlet 105, which can be used for any kind of precursors, reactants, reactive gases and the like, is in fluid communication with the plenum 113. In some embodiments, the processing chamber has a feed inlet at other positions of the chamber (e.g., through a sidewall or bottom).

The showerhead 106 can be made of any suitable material having any suitable thickness. In some embodiments, the showerhead 106 comprises aluminum or stainless steel. In some embodiments, the showerhead faceplate 110 has a thickness Ti in a range of about 2 mm (77 mils) to about 50 mm (1968 mils), or in the range of about 3 mm (118 mils) to about 25 mm (984 mils), or in the range of about 4 (157 mils) mm to about 10 mm (393 mils), and all values and subranges therebetween.

With regard to FIG. 3, showing an enlarged view of the passage 111 in the showerhead faceplate 110. The passage 111 has a longitudinal axis “L”, the back surface diameter DA of a first conical bore section 111A at the back surface 112, and the front surface diameter DB of a second conical bore section 111B at the front surface 114. In one or more embodiments, the front surface diameter DB is smaller than the back surface diameter DA.

In one or more embodiments, a range of the back surface diameter DA of the first conical bore section 111A is greater than or equal to 10 mil (254 micrometers) to less than or equal to 90 mil (2.28 millimeters), and all values and subranges therebetween. In one or more embodiments, a range of the front surface diameter DB of the second conical bore section 111B is greater than or equal to 10 mil (254 micrometers) to less than or equal to 80 mil (2.03 millimeters), and all values and subranges therebetween.

The front and back diameters of the passages 111 can vary depending on, for example, the use of the gas distribution apparatus 106. For example, for chemical vapor deposition (CVD) processes, the front and back diameters of some embodiments are smaller than for atomic layer deposition (ALD) processes. In one or more embodiments, the plurality of passages are uniformly-sized and -shaped. Reference to “uniformly-sized and -shaped” means that dimensions are within manufacturing tolerances for all of the passages. None are sized or shaped differently from each other.

The first conical bore section 111A is defined by an inlet sloped surface 118. The first conical bore section 111A comprises a first non-perpendicular wall angle relative to the back surface 112 of the faceplate 110. Reference to “non-perpendicular to each other” means that an angle of the surfaces is not 90°±2°. The first conical bore section 111A has an entry opening 140, which has an entry angle AA. The entry angle AA of the inlet sloped surface 118 to the back surface 112 relative to a longitudinal axis “L” of the passage 111 is in a range of greater than or equal to 20° to less than or equal to 40°, and all values and subranges therebetween.

The small bore section 111C is defined by cylindrical wall 122 having a diameter Dc. The entry sloped surface 118 has a non-perpendicular angle at corner/edge 136 where it meets the small bore section 111C. In one or more embodiments, the cylindrical wall 122 of the small bore section 111C is co-axial with the longitudinal axis “L” of the passage 111.

The second conical bore section 111B is defined by an outlet sloped surface 120. The second conical bore section 111B comprises a second non-perpendicular wall angle relative to the front surface 114 of the faceplate 110. Reference to “non-perpendicular to each other” means that an angle of the surfaces is not 90°±2°. The second conical bore section 111B has an exit opening 142, which has an exit angle AB. The exit angle AB of the outlet sloped surface 120 to the front surface 114 relative to the longitudinal axis “L” of the passage 111 is in a range of greater than or equal to 20° to less than or equal to 40°, and all values and subranges therebetween.

The entry sloped surface 118 has a first height H₁ measured perpendicularly from the back surface 112 at corner/edge 132 to its intersection with the cylindrical wall 122 at corner edge 136. In some embodiments, the first height H₁ is in a range of about 745 micrometers (29 mils) to about 20 mm (752 mils), and all values and subranges therebetween.

The exit sloped surface 120 has a second height H₂ measured perpendicularly from the front surface 114 at corner/edge 134 to its intersection with the cylindrical wall 122 at corner/edge 138. The cylindrical wall 122 has a third height H₃ between its intersections with the entry sloped surface 118 at the corner/edge 136 and the exit sloped surface 120 at the corner/edge 138. In some embodiments, the second height H₂ is in a range of about 745 micrometers (29 mils) to about 20 mm (752 mils), and all values and subranges therebetween.

In one or more embodiments, the first height H₁ of the entry sloped surface 118 to the cylindrical wall 122 is larger than a second height of the exit sloped surface 120 to the cylindrical wall 122.

In summary, gas distribution apparatus comprises: a faceplate and a plurality of passages extending through a thickness of the faceplate. The faceplate has a front surface and a back surface defining the thickness. Each of the passages has first conical bore section, a small bore section, and a second conical bore section. The first conical bore sections comprise a first non-perpendicular wall angle relative to a back surface of a faceplate. The second conical bore sections comprise a second non-perpendicular angle to a front surface of the faceplate. The conical sections including non-perpendicular angles are effective to mitigate and/or eliminate changes in flow parameters through the passages after bead blast processes.

Turning to FIG. 4, the processing chamber 100 optionally comprises further components, not shown, as-needed. For example, the processing chamber 100 may further comprise: one or more of a vacuum outlet, and a purge gas inlet defining an outer periphery of the process gap 125. In this way, the processing chamber may further comprise a “gas curtain” that inhibits and/or prevents process gases from within the process gap 125 from migrating from the process gap 125 into the other areas of the process chamber 100.

Some embodiments of the processing chamber 100 include a controller 190 coupled to various components of the processing chamber 100 to control the operation thereof. The controller 190 of some embodiments controls the entire processing chamber (not shown). In some embodiments, the processing chamber 100 includes multiple controllers, of which controller 190 is a part; each controller is configured to control one or more individual portions of the processing chamber. For example, the processing chamber of some embodiments comprises separate controllers for one or more of the process gas flow into the showerhead, purge gas flow, vacuum pressure, process gap size, temperature control, and/or actuators.

The controller 190 may be one of any form of general-purpose computer processor, microcontroller, microprocessor, etc., that can be used in an industrial setting for controlling various chambers and sub-processors. The at least one controller 190 of some embodiments has a processor 192, a memory 194 coupled to the processor 192, input/output devices 196 coupled to the processor 192, and support circuits 198 to communication between the different electronic and physical components. The memory 194 of some embodiments includes one or more of transitory memory (e.g., random access memory) and non-transitory memory (e.g., storage).

The memory 194, or a computer-readable medium, of the processor may be one or more of readily available memory such as random access memory (RAM), read-only memory (ROM), floppy disk, hard disk, or any other form of digital storage, local or remote. The memory 194 can retain an instruction set that is operable by the processor 192 to control parameters and components of the system. The support circuits 198 are coupled to the processor 192 for supporting the processor in a conventional manner. Circuits may include, for example, cache, power supplies, clock circuits, input/output circuitry, subsystems, and the like. Circuits also include motors, actuators, gauges (e.g., thermocouple, pyrometer, manometers), valves, etc., that are used to operate the process chamber and control the components that support the methods.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

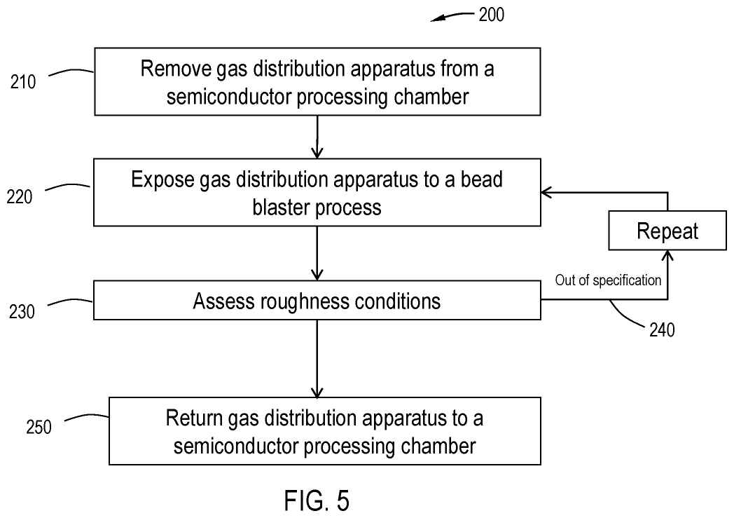

FIG. 5 shows a flowchart of a method 200 of a roughening a gas distribution apparatus in accordance with one or more embodiments. At operation 210, a gas distribution apparatus according to any embodiment herein is removed from a semiconductor processing chamber. At operation 220, the gas distribution apparatus is exposed to a bead blaster process. In one or more embodiments, the front surface and/or the back surface of the gas distribution apparatus are independently contacted. At operation 230, roughness conditions of the gas distribution apparatus are assessed. At operation 240, if the conditions are not in specification, then the bead blaster is operated further. At operation 250, if roughness is acceptable then the gas distribution apparatus is returned to a semiconductor processing chamber.

A bead blaster is a machine configured to roughen surfaces of articles, including gas distribution apparatuses. Bead blasters may be a bead blasting cabinet, a hand held bead blaster, an automatic bead blaster, or other type of bead blaster. The surface roughness can be achieved for different applications. In one or more embodiments, the bead blaster uses ceramic beads to blast a surface of the gas distribution apparatus. The bead blaster may bead blast the apparatus at suitable air pressure, working distance, blasting angle, and bead size.

In one or more embodiments, instructions executed by a controller of a processing chamber, causes the processing chamber to perform operation of: providing a flow one or more gasses to a gas distribution plate according to any embodiment herein; and conducting a semiconductor process in the processing chamber.

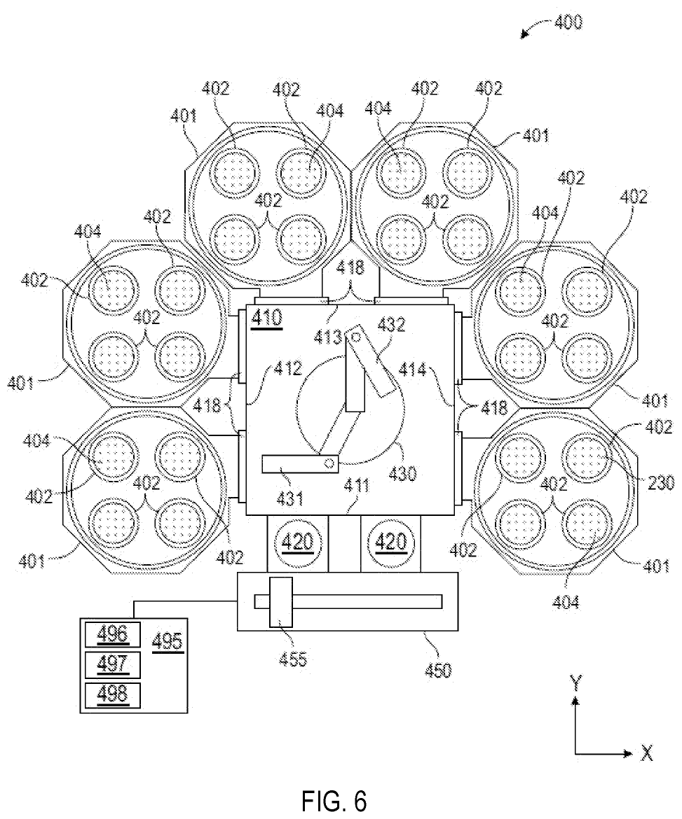

FIG. 6 shows a processing platform 400 in accordance with one or more embodiments that may include any processing chamber and gas distribution apparatus herein. The embodiment shown in FIG. 6 is merely representative of one possible configuration and should not be taken as limiting the scope of the disclosure. For example, in some embodiments, the processing platform 400 has a different number of one or more of the processing chambers 401, buffer stations 420 and/or robot 430 configurations than the illustrated embodiment. Each of the processing chambers 401 has a plurality of process stations 402. Each of the processing stations 402 comprises a substrate support surface 404. In one or more embodiments, each of the processing stations 402 further comprises three main components: a top plate (also called a lid), a pump/purge insert, and a gas injector.

The exemplary processing platform 400 includes a central transfer station 410 which has a plurality of sides 411, 412, 413, 414. The transfer station 410 shown has a first side 411, a second side 412, a third side 413 and a fourth side 414. Although four sides are shown, those skilled in the art will understand that there can be any suitable number of sides to the transfer station 410 depending on, for example, the overall configuration of the processing platform 400. In some embodiments, there the transfer station 410 has three sides, four sides, five sides, six sides, seven sides or eight sides.

The transfer station 410 has a robot 430 positioned therein. The robot 430 can be any suitable robot capable of moving a substrate during processing. In some embodiments, the robot 430 has a first arm 431 and a second arm 432. The first arm 431 and second arm 432 can be moved independently of the other arm. The first arm 431 and second arm 432 can move in the x-y plane and/or along the z-axis. In some embodiments, the robot 430 includes a third arm (not shown) or a fourth arm (not shown). Each of the arms can move independently of other arms.

The embodiment illustrated includes six processing chambers 401 with two connected to each of the second side 412, third side 413 and fourth side 414 of the central transfer station 410. Each of the processing chambers 401 can be configured to perform different processes.

The processing platform 400 can also include one or more buffer station 420 connected to the first side 411 of the central transfer station 410. The buffer stations 420 can perform the same or different functions. For example, the buffer stations may hold a cassette of substrates which are processed and returned to the original cassette, or one of the buffer stations may hold unprocessed substrates which are moved to the other buffer station after processing. In some embodiments, one or more of the buffer stations are configured to pre-treat, pre-heat or clean the substrates before and/or after processing.

The processing platform 400 may also include one or more slit valves 418 between the central transfer station 410 and any of the processing chambers 401. The slit valves 418 can open and close to isolate the interior volume within the processing chamber 401 from the environment within the central transfer station 410. For example, if the processing chamber will generate plasma during processing, it may be helpful to close the slit valve for that processing chamber to prevent stray plasma from damaging the robot in the transfer station.

The processing platform 400 can be connected to a factory interface 450 to allow substrates or cassettes of substrates to be loaded into the processing platform 400. A robot 455 within the factory interface 450 can be used to move the substrates or cassettes into and out of the buffer stations. The substrates or cassettes can be moved within the processing platform 400 by the robot 430 in the central transfer station 410. In some embodiments, the factory interface 450 is a transfer station of another cluster tool (i.e., another multiple chamber processing platform).

A controller 495 may be provided and coupled to various components of the processing platform 400 to control the operation thereof. The controller 495 can be a single controller that controls the entire processing platform 400, or multiple controllers that control individual portions of the processing platform 400. For example, the processing platform 400 of some embodiments comprises separate controllers for one or more of the individual processing chambers 401, central transfer station 410, factory interface 450 and/or robots 430.

In some embodiments, the processing chamber 401 further comprises a controller 495 connected to the plurality of substantially coplanar support surfaces 404 configured to control one or more of the first temperature or the second temperature.

In some embodiments, the controller 495 includes a central processing unit (CPU) 496, a memory 497, and support circuits 498. The controller 495 may control the processing platform 400 directly, or via computers (or controllers) associated with particular process chamber and/or support system components.

The controller 495 may be one of any form of general-purpose computer processor that can be used in an industrial setting for controlling various chambers and sub-processors. The memory 497 or computer readable medium of the controller 495 may be one or more of readily available memory such as random access memory (RAM), read only memory (ROM), floppy disk, hard disk, optical storage media (e.g., compact disc or digital video disc), flash drive, or any other form of digital storage, local or remote. The memory 497 can retain an instruction set that is operable by the processor (CPU 496) to control parameters and components of the processing platform 400.

The support circuits 498 are coupled to the CPU 496 for supporting the processor in a conventional manner. These circuits include cache, power supplies, clock circuits, input/output circuitry and subsystems, and the like. One or more processes may be stored in the memory 497 as software routine that, when executed or invoked by the processor, causes the processor to control the operation of the processing platform 400 or individual processing chambers in the manner described herein. The software routine may also be stored and/or executed by a second CPU (not shown) that is remotely located from the hardware being controlled by the CPU 496.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 495 has one or more configurations to execute individual processes or sub-processes to perform the method. The controller 495 can be connected to and configured to operate intermediate components to perform the functions of the methods. For example, the controller 495 can be connected to and configured to control one or more of gas valves, actuators, motors, slit valves, vacuum control or other components.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A gas distribution apparatus comprising:
a faceplate having a front surface and a back surface defining a thickness; and
a plurality of passages extending through the thickness, each of the passages having a first conical bore section, a small bore section, and a second conical bore section, wherein:
each of the first conical bore sections comprise a first non-perpendicular wall angle relative to the back surface of the faceplate;
each of the small bore sections is defined by a cylindrical wall; and
each of the second conical bore sections comprise a second non-perpendicular angle to the front surface of the faceplate.

2. The gas distribution apparatus of claim 1 in the form of a showerhead.

3. The gas distribution apparatus of claim 1, wherein the plurality of passages are uniformly-sized and -shaped.

4. The gas distribution apparatus of claim 1 wherein the front surface and the back surface each independently has a roughness value in a range of greater than or equal to 24 μ-in Ra to less than or equal to 300 μ-in Ra.

5. The gas distribution apparatus of claim 1, wherein an entry angle of the first conical bore section is in a range of greater than or equal to 20° to less than or equal to 40°.

6. The gas distribution apparatus of claim 1, wherein an exit angle of the second conical bore section is in a range of greater than or equal to 20° to less than or equal to 40°.

7. The gas distribution apparatus of claim 1, wherein a first height of the first conical bore section from the back surface to a first corner of the small bore section is larger than a second height of the second conical bore section to a second corner of the small bore section.

8. The gas distribution apparatus of claim 1, wherein the cylindrical wall of each of the small bore sections is co-axial with a longitudinal axis of each of the passages.

9. The gas distribution apparatus of claim 1, wherein the thickness of the faceplate is in a range of greater than or equal to 2 mm to less than or equal to 50 mm.

10. A showerhead comprising:
a faceplate having a front surface and a back surface defining a thickness; and
a plurality of uniformly-sized and -shaped passages extending through the thickness, each of the passages having a first conical bore section, a small bore section, and a second conical bore section, wherein:
each of the first conical bore sections comprise a first non-perpendicular wall angle relative to the back surface of the faceplate, and an entry angle in a range of greater than or equal to 20° to less than or equal to 40°;
each of the small bore sections is defined by a cylindrical wall that is co-axial with a longitudinal axis of each of the passages;
each of the second conical bore sections comprise a second non-perpendicular angle to the front surface of the faceplate, and an exit angle is in a range of greater than or equal to 20° to less than or equal to 40°; and
the front surface and the back surface each independently has a roughness value in a range of greater than or equal to 10 μ-in Ra to less than or equal to 300 μ-in Ra.

11. The showerhead of claim 10, wherein the thickness of the faceplate is in a range of greater than or equal to 2 mm to less than or equal to 50 mm, and/or a back surface diameter of each of the passages is in a range of greater than or equal to 10 mil (254 micrometers) to less than or equal to 90 mil (2.28 millimeters).

12. A semiconductor processing chamber comprising:
a housing;
a substrate support having a support surface; and
the gas distribution apparatus of claim 1, wherein the front surface of the faceplate is spaced a distance from the support surface.

13. The semiconductor processing chamber of claim 12 further comprising a controller configured to provide a flow of gas to the gas distribution apparatus.

14. The semiconductor processing chamber of claim 12, wherein the gas distribution apparatus is in the form of a showerhead.

15. The semiconductor processing chamber of claim 12, wherein the plurality of passages are uniformly-sized and -shaped.

16. The semiconductor processing chamber of claim 12, wherein the front surface and the back surface each independently has a roughness value in a range of greater than or equal to 24 μ-in Ra to less than or equal to 300 μ-in Ra.

17. The semiconductor processing chamber of claim 12, wherein an entry angle of the first conical bore section is in a range of greater than or equal to 20° to less than or equal to 40° and/or an exit angle of the second conical bore section is independently in a range of greater than or equal to 20° to less than or equal to 40°.

18. The semiconductor processing chamber of claim 12, wherein a first height of the first conical bore section from the back surface to a first corner of the small bore section is larger than a second height of the second conical bore section to a second corner of the small bore section.

19. The semiconductor processing chamber of claim 12, wherein the cylindrical wall of each of the small bore sections is co-axial with a longitudinal axis of each of the passages.

20. The semiconductor processing chamber of claim 12, wherein the thickness of the faceplate is in a range of greater than or equal to 2 mm to less than or equal to 50 mm and/or a back surface diameter of each of the passages is in a range of greater than or equal to 10 mil (254 micrometers) to less than or equal to 90 mil (2.28 millimeters).
